(19) United States
(12) Patent Application Publication
(10) Pub. No.: US 2006/0178211 A1
(43) Pub. Date: Aug. 10, 2006

(54) Remote controller sweat installation

(76) Inventor: Hung Wen Chien, Chung-Ho City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/051,002

(22) Filed: Feb. 7, 2005

(51) Int. Cl. A63F 13/00; H03K 17/94; H05K 7/20

(52) U.S. Cl. 463/37; 341/20; 361/688

(57) ABSTRACT

A remote controller sweat installation comprised of multiple sweat pores arranged at equal spacing on the surface of the controller where contacts hands of its user and multiple protruding tubes disposed on the inner edge of the controller in relation to those pores with each tube containing a capillary connecting through its corresponding pore for the sweat from the hands of the controller user to be soonest vaporized through pores, capillaries, and terminals of tubes in sequence by taking advantage of the capillary attraction.

### BACKGROUND OF THE INVENTION

(a) Field of the Invention

The present invention is related to a remote controller sweat installation, and more particularly to one that achieves rapid vaporization of sweat by taking advantage of capillary attraction.

(b) Description of the Prior Art

There is the absence of any construct to dispel sweats from the hands of the user of a remote controller, e.g., a TV game controller or a mouse, of the prior art. Sweats from hands thus all over the surface of the controller make the controller sticky to allow easy holding.

An improvement has been developed as illustrated in FIG. 1 of the accompanying drawings by having provided multiple sweat pores 11 arranged at equal spacing from one another on the surface of the controller 1 to dispel sweats through those pores 11 into the controller 1 to be vaporized therein. However, those pores relate to simple through holes and sweats could easily get stuck in those pores 11 due to surface tension to prevent evaporating those sweats. Once again, sweats are all over the surface of the controller 1.

### SUMMARY OF THE INVENTION

The primary purpose of the present invention is to provide a remote controller sweat installation for rapid vaporization of sweat by taking advantage of capillary attraction.

To achieve the purpose, multiple sweat pores are arranged at equal spacing on the surface of the controller where contacts hands of its user, and multiple protruding tubes disposed on the inner edge of the controller in relation to those pores with each tube containing a capillary connecting through its corresponding pore. Accordingly, sweats from the hands of the user of the controller are vaporized through pores, capillaries, and terminals of tubes in sequence by taking advantage of the capillary attraction.

### BRIEF DESCRIPTION OF THE DRAWINGS

FIG. 1 is a perspective view of the prior art.

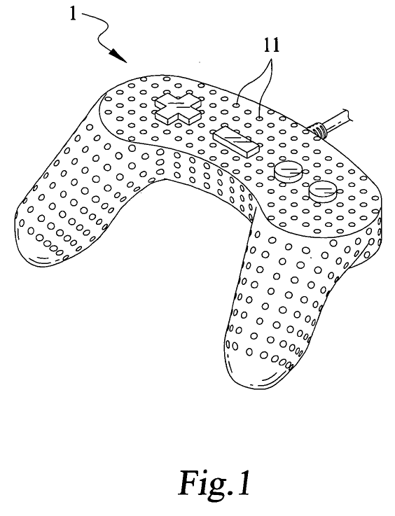

FIG. 2 is a perspective view of a preferred embodiment of the present invention.

FIG. 3 is a sectional view of a cut-away of the preferred embodiment of the present invention.

### DETAILED DESCRIPTION OF THE PREFERRED EMBODIMENTS

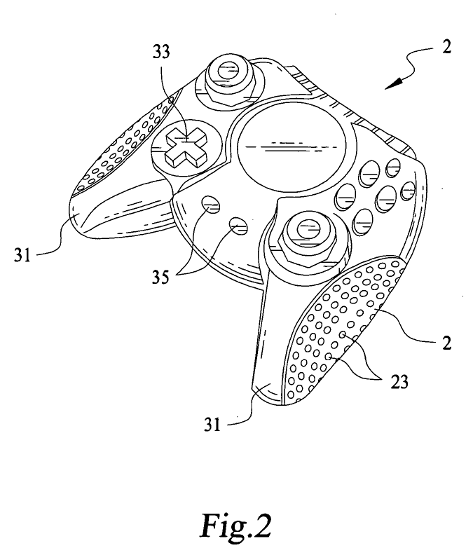

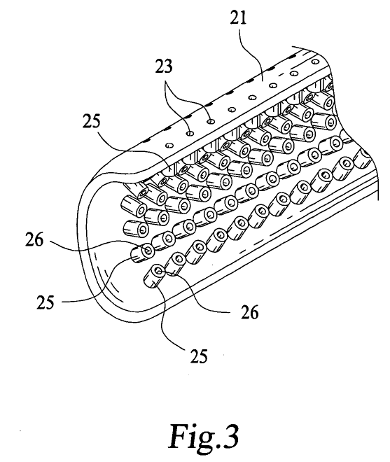

Referring to FIGS. 2 and 3, a remote controller sweat installation of the present invention is comprised of multiple sweat pores 23 arranged at equal spacing from one another on a surface 21 of a controller 2 where contacts both hands of the user. Multiple protruding tubes 25 are disposed on the inner edge of the controller 2 in relation to those pores 23. Each tube 25 contains a capillary 26 connecting through its corresponding pore 23.

Sweats from the hands of user holding the remote controller 2 are vaporized through those pores 23, capillaries 26, and terminals of those tubes 25 in sequence thanks to the capillary attraction provided by those capillaries 26.

As illustrated in FIGS. 2 and 3, the remote controller 2 relates to a TV game controller adapted with a pair of grips 31 for the user to hold on to. Multiple sweat pores 23 are arranged at equal spacing from on another on the surfaces where contact both hands of the user. Multiple protruding tubes 25 are disposed on the inner edge of the TV game controller in relation to those pores 23. Each protruding tube 25 contains a capillary 26 connecting through its corresponding pore 23. A fan (not illustrated) is built in the remote controller 2. Accordingly, sweats from both hands are vaporized through those pores 23, capillaries 26 and terminals of those tubes 25 in sequence by riding on the air currents created by the fan.

One or a plurality of direction keys 33 is provided on the TV game controller for the player to control direction of the cursor on the screen. Multiple control keys 35 are also provided on the remote controller for the player to input commands of the TV game software. The player enjoys the game by operating those direction keys 33 and control keys 35.

The remote controller sweat installation of the present invention is innovative and not yet has been disclosed in the market or any publications. Furthermore, the present invention eliminates those defectives found with the prior art. Therefore, this application for a utility patent is duly filed accordingly.

It is to be noted that the preferred embodiment given in the specification is by no means limiting the construction of the present invention. Any modification or alternation that can be easily done by those who are familiar with this art shall fall within the scope of claims made by the preference invention.

1. A remote controller sweat installation includes:
multiple sweat pores arranged in equal spacing on the remote controller where contacts hands of its user; and
multiple protruding tubes disposed on the inner edge of the remote controller at where in relation to those pores, each tube containing a capillary connecting through its corresponding pore for sweat from the hands of the user to be vaporized through those pores, capillaries, and terminals of those tubes in sequence by means of capillary attraction.

2. The remote controller sweat installation of claim 1, wherein the remote controller related to a TV game controller.

3. The remote controller sweat installation of claim 1, wherein a fan is built in the controller.
